(19) United States
(12) Patent Application Publication
(10) Pub. No.: US 2018/0159022 A1
(43) Pub. Date: Jun. 7, 2018

(54) ELECTROMECHANICAL CONVERTER CONSISTING OF A CYCLICALLY STABLE, REVERSIBLE, AND EXPANDABLE ELECTRODE, AND A METHOD FOR PRODUCING SAME

(71) Applicant: Covestro Deutschland AG, Leverkusen (DE)

(72) Inventors: Jens KRAUSE, Leverkusen (DE); Enrico ORSELLI, Köln (DE)

(73) Assignee: Covestro Deutschland AG, Leverkusen (DE)

(21) Appl. No.: 15/577,810

(22) PCT Filed: May 24, 2016
(86) PCT No.: PCT/EP2016/061676

§ 371 Date: Nov. 29, 2017

(30) Foreign Application Priority Data
May 29, 2015 (EP) 15169895.8

(51) Int. Cl. H01L 41/297; H01L 41/047; H01L 41/193

(52) U.S. Cl. CPC H01L 41/297; H01L 41/193; H01L 41/0478; H01L 41/0471

(57) ABSTRACT

The invention relates to thin, flexible and expandable electrically conductive electrode layers based on conductive carbon, said layers having a sufficiently high adhesion to dielectric layers in stacking actuators without delamination. The invention also relates to a method for producing said electrode layers, to the use thereof for producing electromechanical converters based on dielectric elastomers as well as components comprising the electromechanical converter, to a use of the electromechanical converter, and to a device for producing the electroactive polymer film system and the electromechanical converter from multilayer actuators.

The invention relates to electrically conductive, flexible, extensible and thin electrode layers based on conductive carbon which, in stack actuators, have sufficiently high adhesion to dielectric layers without delamination, to a process for production thereof and to the use thereof for production of electromechanical transducers based on dielectric elastomers, and to components comprising the electromechanical transducer, to use of the electromechanical transducer, and to an apparatus for production of the electroactive polymer film system and of the electromechanical transducer from multilayer actuators.

Electromechanical transducers convert electrical energy into mechanical energy and vice versa. They can be used as a component part of sensors, actuators and/or generators.

The basic construction of such a transducer consists of electroactive polymers EAP. The principle of construction and the mode of action are similar to those of an electrical capacitor. A dielectric is present between two conductive electrodes to which a voltage is applied. However, EAPs are an extensible dielectric which deforms in a way depending on the electrical field. More specifically, they are dielectric elastomers, usually in the form of DEAP films (dielectric electroactive polymer), which have high electrical resistivity and are coated on both sides with extensible electrodes of high conductivity, as described, for example, in WO 01/006575 A. This basic construction can be used in a wide variety of different configurations for the production of sensors, actuators or generators. As well as single-layer constructions, multilayer electromechanical transducers are also known.

Depending on the application, such as an actuator, a sensor and/or a generator, electroactive polymers as an elastic dielectric in such transducer systems have different electrical and mechanical properties.

The electrical properties they share are a high internal electrical resistance of the dielectric, a high dielectric strength, a high electrical conductivity of the electrode and a high dielectric constant in the frequency range of the application. These properties allow long-term storage of a large amount of electrical energy in the volume filled with the electroactive polymer.

Mechanical properties present in all cases are sufficiently high elongation at break, low permanent extension values and sufficiently high compressive/tensile strengths. These properties ensure sufficiently high elastic deformability without mechanical damage to the energy transducer.

For electromechanical transducers that are operated “under tension”, i.e. are subjected to tensile stress during operation, it is particularly important that these elastomers do not have any permanent extension. In particular, no flow or “creep” should occur, since otherwise, after a certain number of cycles of extensions, there is no longer any mechanical restoring force, and consequently there is no longer any electroactive effect. Therefore, the elastomers should not display any stress relaxation under a mechanical load.

For electromechanical transducers in tension mode, elastomers of highly reversible extensibility with high elongation at break and low tensile modulus of elasticity are required. The literature in respect of electromechanical transducers of this kind discloses that extensibility is proportional to dielectric constant and applied voltage to the power of two, and also inversely proportional to modulus. With relative permittivity εᵣ, absolute permittivity ε₀, stiffness Y, film thickness d and electrical voltage U, extension s_{z} is according to the equation:

$${s}_{z} = \frac{{σ}_{Maxwell}}{Y} = \frac{{ɛ}_{0} \cdot {ɛ}_{r}}{Y} {( \frac{U}{d} )}^{2} . \qquad 1$$

The maximum possible electrical voltage is in turn dependent on the breakdown field strength. A low breakdown field strength has the consequence here that only low voltages can be applied. Since the square of the value of the voltage is entered in the equation for calculating the extension that is caused by the electrostatic attraction of the electrodes, the breakdown field strength is preferably correspondingly high. Particularly for applications close to the end user, however, the implementation of low operating voltages is important. In this case often small size and low power, but this is also associated with low operating voltage.

An equation known from the prior art for this can be found in the book by Federico Carpi, Dielectric Elastomers as Electromechanical Transducers, Elsevier, page 314, equation 30.1, and similarly also in R. Pelrine, Science 287, 5454, 2000, page 837, equation 2. The equation from the above paragraph makes clear a very important property for the operation of dielectric elastomer actuators: The lower the layer thickness d, the smaller the operating voltage of the actuators can be with the same electrical field strength.

At the same time, however, the absolute deformation amplitude possible in the direction of the thickness also falls with the layer thickness.

A way out of this problem has already been shown by PELRINE et al., in an early publication from 1997: Analogously to piezoelectric stack actuators, it is possible to stack individual layers one on top of another [R. E. PELRINE, R. KORNBLUH, J. P. JOSEPH and S. CHIBA, “Electrostriction of polymer films for microactuators”, in: Micro Electro Mechanical Systems, 1997. MEMS '97, Proceedings, IEEE., Tenth Annual International Workshop on 1997, p. 238-243.]. These layers are electrically connected in parallel, meaning that there is a relatively high field strength E over each layer in spite of low operating voltage U. In mechanical terms, by contrast, the actuator layers are connected in series; the individual deformations are additive. The stack demonstrated by PELRINE et al. had four layers of dielectric and electrode and was produced manually. The electrode layers preferably have a certain structure, which can be achieved by a spray mask, inkjet printing and/or a screen in the case of screen printing.

A similar effect can be achieved if the elastomer films coated with electrode layers are rolled up. In this case, the deformation forces are no longer used in the direction of the applied electrical field, but at right angles thereto. Two principles for this are known:

Danfoss Polypower uses corrugated EAP material to construct a coreless rolled actuator [Tryson, M., Kiil, Benslimane, H.-E., Benslimane, M.: Powerful tubular core free dielectric electro activate polymer DEAP ‘PUSH’ actuator; Electroactive Polymer Actuators and Devices EAPAD, Proc. of SPIE Vol. 7287, 2009.]; in the EMPA [Zhang, R., Lochmatter, P., Kunz, A., Kovacs, G.: Spring Roll Dielectric Elastomer Actuators for a Portable Force Feedback Glove; Smart Structures and Materials, Proc, of SPIE Vol. 6168, 2006.] the EAP material was prestressed with the aid of an integrated helical spring. A disadvantage in the case of the last principle is the high susceptibility to mechanical defects in the EAP material. The actuator effect in the case of the coreless actuator is attributable just to the circumferentially stiff electrode.

A great challenge in the production of a stack actuator or a multilayer electromechanical transducer in the case of all methods is the faultless and contamination-free stacking of a multitude of dielectric layers and electrode layers. CARPI et al. identified the cutting-open of a tube as a solution to this problem. The dielectric is in the form of a silicone tube. This tube is cut open in a spiral manner, then the cut faces are covered with conductive material, and these then serve as electrodes [F. CARPI, A. MIGLIORE, G. SERRA and D. DE ROSSI. “Helical dielectric elastomer actuators”, in: Smart Materials and Structures 14.6 (2005), p. 1210-1216].

CHUC et al. presented an automated process which in principle is based on the folding according to CARPI [N. H. CHUC, J. K. PARK, D. V. THUY, H. S. KIM, J. C. KOO et al. “Multi-stacked artificial muscle actuator based on synthetic elastomer”, in: Proceedings of the 2007 IEEE/RSJ International Conference on Intelligent Robots and Systems San Diego, Calif., USA, Oct. 29-Nov. 2, 2007 2007, p. 771.]. However, the dielectric films here are each folded only once. The stack actuators of CARPI et al. and CHUC et al. are not designed to absorb tensile forces. Since the electrostatic forces reach only from the outside to the outside of adjacent electrodes, there is the risk of delamination of the stack actuators, since no forces exist within the electrodes. KOVACS and DURING developed a technique for producing extremely thin carbon black layers. Electrodes produced thereby are said to consist only of one layer of primary particles. Such a monolayer builds up electrostatic forces on both adjacent electrodes and is thus capable also of absorbing tensile forces [G. KOVACS and L. DÜRING. “Contractive tension force stack actuator based on soft dielectric EAP”, Electroactive Polymer Actuators and Devices EAPAD 2009, ed. by Y. BAR-COHEN and T. WALLMERSPERGER. Vol. 7287. 1. San Diego, Calif., USA: SPIE, 2009, 72870A-15.].

However, the transducers according to the prior art have three main disadvantages, which are attributable to the insufficiently adapted elastomer, the inadequate industry-based manufacturing technology and the inadequate long-term stability. A disadvantage of all the methods mentioned is that the layers electrode layers and elastomer layers only weakly adhere to one another and joining the structured electrode segments together in a continuous, exactly fitting manner in the processes is either only possible very slowly, and consequently unproductively, or leads to strong displacements of the active surfaces. A further disadvantage is that the electrode layers are too thick and hence inhibit the movement of the active surface based on the dielectric elastomer. Thin electrodes having high conductivity are usually known only on the basis of metals such as silver or aluminum. These metals in turn are regrettably costly and usually brittle, which makes it difficult to use them industrially. Carbon-based thin electrode layers have the features of conductivities that are too low, inadequate extensibility and high creep. Highly conductive layers in turn do not exhibit any adhesion to a joined elastomer layer.

It was therefore an object of the present invention to produce electrically conductive, flexible, extensible, thin structured electrodes, cyclically stable, bondable electrode layers containing conductive carbon, a process for production thereof and the use thereof for production of electromechanical transducers.

At the same time, the electrode is to have the following parameters:
finely divided particles <10 μm in the dispersion and in the electrode layer;
the electrode is to be applied homogeneously to a soft, extensible elastomer film without leading to wetting defects, characterized in that the elastomer has a thickness of <100 μm and a modulus of <10 MPa;
the dry layer thickness of the electrode should be <5 μm, preferably <1 μm, such that the actuatory function of the elastomer is not restricted;
the electrode should adhere to the elastomer layer and, under reversible extension over 1000 cycles with 15% extension at 0.125 Hz, suffer a maximum loss of conductivity of 30% based on the starting value;
the electrode at 0% extension should have a surface resistivity of <10 000 ohms/square and, at 15% extension, a surface resistivity of <50 000 ohms/square;
the composite of elastomer and electrode should have a creep of <15%.

The dispersion of the carbon particles in the process of the invention is preferably effected in dispersing units with high local energy input, preferably by means of dispersing disks and rotor-stator systems, for example colloid mills, toothed dispersing machines, etc. The rotor-stator principle is a technique known per se, by which fillers or the like are distributed homogeneously in liquid media under high shear forces. With rotor-stator machines, it is possible to disperse liquid and solid media in a liquid matrix. The technique and the machines used are described in detail in Rotor-Stator and Disc Systems for Emulsification Processes; Kai Urban, Gerhard Wagner, David Schaffner, Danny Röglin, Joachim Ulrich; Chemical Engineering & Technology, 2006, vol. 29, no. 1, pages 24 to 31; DE-A 10 2005 006 765, DE-A 197 20 959 and U.S. Pat. No. 3,054,565.

### SUMMARY OF THE INVENTION

One aspect of the present invention relates to a process for producing a laminate comprising an electrode layer and a dielectric layer, comprising the steps of:
I. applying a starting mixture for production of an electrode layer to a dielectric elastomer film, where the starting mixture consists of
   a) an organic or aqueous solvent present in the starting mixture in the range from 50% by weight to 97% by weight based on the sum total of a, b, c, d, e and f; and
   the sum total of b, c, d, e and fin the starting mixture is in the range from 50% by weight to 3% by weight based on the sum total of a, b, c, d, e and fin the starting mixture; where
   b) is a dispersing aid, and
   c) is a starting material for formation of a matrix polymer, preferably for formation of an elastomer, and
   d) is at least one conductive carbon black having a BET surface area of ≥1000 m²/g measured by the BET method according to ASTM D 6556-04, as at Apr. 27, 2015, and
   (e) is at least one conductive carbon black having a BET surface area of <1000 m²/g, preferably <900 m²/g, more preferably <600 m²/g, measured by the BET method according to ASTM D 6556-04, as at Apr. 27, 2015, and
   f) is at least one further auxiliary or additive, and
   where
      the proportion by weight of h in the sum total of b c, d, e and f is in the range from 1 to 20 parts by weight,
      the proportion by weight of c in the sum total of h, c, d, e and f is in the range from 10 to 70 parts by weight,
      the proportion by weight of d in the sum total of b, c, d, e and f is in the range from 1 to 20 parts by weight,
      the proportion by weight of e in the sum total of b, c, d, e and f is in the range from 1 to 60 parts by weight,
      the proportion by weight off in the sum total of b, c, d, e and f is in the range from 0 to 20 parts by weight,
when the sum total of b, c, d, e and f is set to 100;
II. drying the layer at 30 to 150° C.

A preferred embodiment relates to the process described herein, wherein the starting material for formation of a matrix polymer leads to formation of a polyurethane.

A further preferred embodiment relates to the process described herein, wherein the ratio of d) to e) is in the range from 10:1 to 1:20, preferably in the range from 5:1 to 1:15, more preferably in the range from 1:2 to 1:10.

A further preferred embodiment relates to the process described herein, wherein the conductive carbon black having a BET surface area of <1000 m²/g has a BET surface area of <900 m²/g, A further preferred embodiment relates to the process described herein, wherein the conductive carbon black having a BET surface area of <1000 m²/g has a BET surface area in the range from 10 m²/g to 900 m²/g. A further preferred embodiment relates to the process described herein, wherein the conductive carbon black having a BET surface area of <1000 m²/g consists of a mixture of conductive carbon black having a BET surface area of 300 m²/g to 1000 m²/g, preferably 300 m²/g to 900 m²/g, and one having a BET surface area of 50 m²/g to 300 m²/g.

A further preferred embodiment relates to the process described herein, wherein the dry electrode layer thickness is in the range from 0.1 μm to 5 μm, preferably from 0.2 μm to 3 μm, more preferably from 0.3 μm to 1 μm.

A further preferred embodiment relates to the process described herein, wherein conductive carbon black and further auxiliaries and/or additives are mixed in at a power density of 102 kW/m³ to 1014 kW/m³, preferably of 104 kW/m³ to 1013 kW/m³.

A further preferred embodiment relates to the process described herein, wherein the binder may have one or more components.

A further preferred embodiment relates to the process described herein, wherein the layer thickness of the dielectric elastomer film is in the range from 1 μm to 200 μm.

A further preferred embodiment relates to the process described herein, wherein the film-forming polymer of a dielectric elastomer film is polyurethane.

A further preferred embodiment relates to the process described herein, wherein the ratio of electrode layer thickness to dielectric elastomer film layer thickness is <0.06.

A further preferred embodiment relates to the process described herein, further comprising step III;
III. applying a starting mixture for production of a second electrode layer to the surface of the dielectric elastomer film remote from the first layer.

A further preferred embodiment relates to the process described herein, further comprising step IV:
IV applying a further dielectric elastomer film by means of an adhesive to the electrode layer after step II or applying a further dielectric elastomer film by means of an adhesive to one of the two electrode layers after step III or applying one further dielectric elastomer film to each of the two electrode layers after step III.

A further preferred embodiment relates to the process described herein, wherein the second electrode layer is produced in step HI from a composition described by the process of the invention.

A further aspect relates to a laminate consisting of a dielectric layer of elastomer film and an electrode layer, wherein the electrode layer consists of
h) 1% to 20% by weight of dispersing aid,
c) 10% to 70% by weight of matrix polymer, and
d) 1% to 20% by weight of conductive carbon black having a BET surface area of ≥1000 m²/g measured by the BET method according to ASTM D 6556-04, as at Apr. 27, 2015, and
e) 1% to 60% by weight of conductive carbon black having a BET surface area of <1000 m²/g measured by the BET method to ASTM D 6556-04, and
f) 0% to 20% by weight of at least one further auxiliary and/or additive, and
where the sum total of b, c, d, e and f is 100% by weight.

A further aspect relates to an electromechanical actuator comprising a laminate produced by a process of the invention, wherein the electromechanical actuator comprises a first electrode unit on a dielectric elastomer film produced by a process of the invention and a second electrode unit on the side of the dielectric elastomer film remote from the first electrode unit, preferably produced with an electrode layer composition as described herein, a control unit which makes contact with the first and second electrode units and is set up to apply an electrical voltage between the first and second electrode units, and is also set up to allow an electrical current to flow through the first and/or second electrode unit.

A further aspect relates to a multilayer actuator comprising at least one unit consisting of a first electrode unit on a dielectric elastomer film and a second electrode unit on the side of the dielectric elastomer film remote from the first electrode unit, and at least one further dielectric elastomer film which has been bonded by means of an adhesive to one of the two electrode units, wherein this unit has been produced by a process described herein, comprising steps I to IV described herein.

In a preferred embodiment, the actuator consists/comprises a laminate produced by steps I-Ill of a process of the invention and two power connections for each electrode layer.

A further preferred embodiment relates to an actuator further comprising two dielectric elastomer films applied in step IV of a process of the invention.

A further aspect relates to a layer actuator comprising at least two laminates produced by steps I-III, each of which are bonded between two electrode layers with adhesive via a further dielectric elastomer film.

A further aspect relates to a laminate described herein or actuator described herein, wherein the adhesion between the electrode layer and an elastomer layer laminated thereto holds under actuation.

A further aspect relates to a laminate described herein or actuator described herein, wherein the surface resistivity (SR) after cyclic loading of 1000 cycles at 10 Hz and an extension of 10% is still <50 000 ohms/square.

A further aspect relates to a laminate described herein or actuator described herein, wherein the properties of the dielectric elastomer in relation to electrical resistance and electrical breakdown voltage are not impaired.

A further aspect of the invention relates to a process for producing at least one multilayer electromechanical transducer, comprising:
providing at least one dielectric elastomer film,
applying at least one electrode layer according to the present invention to at least a first part of the elastomer film in an application step,
arranging the elastomer film on a receiving surface of a folding device, where the folding device has a first plate and at least one second plate,
fixing the elastomer film on the receiving surface, and
folding the first part of the elastomer film onto a further part of the elastomer film in a folding step by folding the first plate with respect to the second plate in such a way that the electrode layer is arranged between the first part of the elastomer film and the second part of the elastomer film,
optionally stacking two or more folded elastomer films to increase the overall height of the electromechanical transducer.

A further aspect of the invention relates to a process for producing at least one multilayer electromechanical transducer, comprising:
providing at least one dielectric elastomer film,
applying at least one electrode layer according to the present invention to at least a first part of the elastomer film in an application step,
optionally bonding the electrode layer to a further dielectric elastomer film,
sending it to a process for producing multilayer transducers.

Electrode Layer

Electrodes used have to adapt in an ideal manner to the tensile forces during pretensioning/deflection and should not themselves offer any reverse tension, i.e. in simplified terms should ideally be “softer” than the elastomer. An ideal electrode therefore has to have high extensibility and flexibility with constantly high conductivity. What is also important, however, is that the electrode layer is thin compared to the polymer layer, such that homogeneous charge distribution on the adjoining polymer surface is achieved. Electrodes must also maintain their conductivity after many load cycles and be resistant to mechanical stress. Precise structuring of the electrode should be possible, since the charge distribution over the polymer layer can be influenced in a controlled manner, such that complex structures with defined electroactive centers can be configured. These demands on the electrode are all the more important for thinner polymer layers, since the effects are amplified here as described. Particularly for multilayer actuators, electrodes must also be thin, since bulges will otherwise form.

Therefore, it is an object of the present invention to provide an electrode layer for production of an electromechanical transducer/electroactive polymer film system which at least partly reduces the aforementioned disadvantages.

The object derived and presented above is achieved in a first aspect of the invention in a process as claimed in claim 1. The method for producing at least one multilayer electromechanical transducer comprises:
providing at least one dielectric elastomer film,
applying at least one electrode layer to at least a first part of the elastomer film in an application step,
sending it to a process for producing multilayer transducers.

By contrast with the prior art, according to the teaching of the invention, an improved electrode for production of multilayer electromechanical transducers is provided.

The person skilled in the art is familiar with standard layer thicknesses for use in actuators. The layer thickness of an electrode layer produced by the process of the invention is preferably in the range from 0.1 μm to 5 μm, preferably from 0.2 μm to 3 μm, more preferably from 0.3 μm to 1 μm.

Dielectric Elastomer Film

Firstly, at least one dielectric elastomer film or elastomer layer is provided. A dielectric elastomer layer preferably has a relatively high dielectric constant. In addition, a dielectric elastomer layer preferably has a high mechanical stiffness. A dielectric elastomer layer may be used in particular for an actuator application. However, dielectric elastomer layers are similarly suitable for sensor or generator applications.

Furthermore, the dielectric elastomer film may preferably comprise a material selected, for example, from the group of synthetic elastomers comprising polyurethane elastomers, silicone elastomers, acrylate elastomers, e.g. ethylene-vinyl acetate, fluororubber, unvulcanized rubber, vulcanized rubber, polyurethane, polybutadiene, nitrile-butadiene rubber (NBR) or isoprenes and/or polyvinylidene fluoride. Preference is given to using polyurethane elastomers.

Elastomer films, especially polyurethane films, may comprise further constituents such as at least one auxiliary and/or additive as detailed herein in addition to the base polymer.

In a preferred embodiment, an elastomer film provided has at least one first part and a further/second part. For example, the elastomer film may be divided into essentially two parts of the same size. In an application step, at least one electrode layer is applied at least to the first part, in particular to at least an upper side of the first part. Application on both sides is also possible.

Preferably, the thickness of such elastomer films is in the range from 1 μm to 200 μm, more preferably in the range from 1.5 μm to 150 μm, even more preferably in the range from 2 μm to 100 μm.

Solvent

Solvents a used may be aqueous or organic solvents.

It is possible with preference to use a solvent that has a vapor pressure at 20° C. in the range from 0.1 mbar to 200 mbar, preferably in the range from 0.2 mbar to 150 mbar and more preferably in the range from 0.3 mbar to 120 mbar. This solvent can especially be added to the mixture from step I. It is particularly advantageous here that the electrode layers of the invention can be produced on a roll-coating system.

Preference is given to using organic solvents. Preferred organic solvents are protic organic solvents such as alcohols, preferably butanol, aprotic polar solvents such as carboxylic esters or ketones, preferably ethyl acetate, butyl acetate, 1-methoxy-2-propyl acetate, butanone, aprotic nonpolar organic solvents such as toluene xylene. Particularly preferred solvents are ethyl acetate, butyl acetate, toluene, xylene, butanone, n-butanol and 1-methoxy-2-propyl acetate.

Dispersing Aid

Dispersing aids are known to those skilled in the art. Preferred dispersing aids are high molecular weight copolymers, polyurethanes, polyacrylate, polyvinylpyrrolidone, block copolyethers and block copolyethers, carboxymethyl cellulose.

Matrix Polymer

Matrix polymers used in the context of the present invention are electrically conductive polymers and/or oligomers thereof and/or monomers thereof, simply called polymers hereinafter. More particularly, monomers and oligomers frequently constitute the starting materials for formation of a matrix polymer in the processes of the invention.

Elastomers are particularly suitable as matrix polymer for an electrode layer of the invention.

Particularly preferred matrix polymers are polyurethanes, aromatic polyesterpolyurethane, silicones, polysulfones, polyacrylates, aliphatic polyetherpolyurethane and polycarbonate ester polyetherpolyurethane.

The person skilled in the art is aware of the respective starting materials for formation of a matrix polymer; for example, a polyurethane forms by means of polyaddition from polyols and polyisocyanates, for example. The preparation of polyurethanes is sufficiently well known.

Conductive Carbon Black

The expression “conductive carbon black” carbon black—CAS No. 1333-86-4—as used herein is known to the person skilled in the art. This is an industrial carbon black and consists of small, usually spherical primary particles. These usually have a size of 5 to 300 nanometers. These primary particles can form aggregates. Many of these aggregates combine and thus form agglomerates. By the variation of the production conditions, it is possible to control both the size of the primary particles and the aggregation thereof.

Conductive carbon blacks can have various values for BET surface areas (Brunauer Emmett Teller isotherm for description of surfaces). The BET value of a surface can be determined by means of ASTM D 6556-04, as at Apr. 1, 2015.

According to the invention, an electrode layer comprises at least one conductive carbon black having a BET surface area of ≥1000 m²/g measured by the BET method to ASTM D 6556-04, as at Apr. 27, 2015, and at least one conductive carbon black having a BET surface area of <1000 m²/g, for example measured by the BET method to ASTM D 6556-04, as at Apr. 27, 2015. The ratio here of conductive carbon black having a BET surface area of ≥1000 m²/g to conductive carbon black having a BET surface area of <1000 m²/g is in the range from 10:1 to 1:20, preferably in the range from 5:1 to 1:15, more preferably in the range from 5:1 to 1:15, even more preferably in the range from 1:2 to 1:10.

In a preferred embodiment, the surface area of each conductive carbon black having a BET surface area of <1000 m²/g in a layer of the invention is <900 m²/g, more preferably <600 m²/g; for example, the surface area is within a range from 1 m²/g to 900 m²/g, more preferably within a range from 1 m²/g to 600 m²/g, or in a further, more preferred embodiment within a range from 50 m²/g to 900 m²/g, even more preferably within a range from 50 m²/g to 600 m²/g.

In a further preferred embodiment, the proportion of conductive carbon black(s) having a BET surface area of ≥1000 leg measured by the BET method to ASTM D 6556-04, as at Apr. 27, 2015, in an electrode layer after drying is in the range from 2% to 15% by weight, based on the sum total of b, c, d, e and f, more preferably 2% to 10% by weight based on the sum total of a), c, d, e and f.

In a further preferred embodiment, the proportion of conductive carbon black(s) having a BET surface area of <1000 m²/g measured by the BET method to ASTM D 6556-04, as at Apr. 27, 2015, in an electrode layer after drying is in the range from 5% to 55% by weight, based on the sum total of h, c, d, e and f, more preferably 20% to 50% by weight based on the sum total of b, c, d, e and f.

In a further preferred embodiment, the proportion of conductive carbon black(s) having a BET surface area of ≥1000 m²/g measured by the BET method to ASTM ID 6556-04, as at Apr. 27, 2015, in an electrode layer after drying is in the range from 2% to 15% by weight, based on the sum total of b, c, d, e and f, and the proportion of conductive carbon black(s) having a BET surface area of <1000 m²/g measured by the BET method to ASTM D 6556-04, as at Apr. 27, 2015, in an electrode layer after drying is in the range from 5% to 55% by weight, based on the sum total of b, c, d, e and f.

In a further, more preferred embodiment, the proportion of conductive carbon black(s) having a BET surface area of ≥1000 m²/g measured by the BET method to ASTM D 6556-04, as at Apr. 27, 2015, in an electrode layer after drying is in the range from 2% to 10% by weight, based on the sum total of b, c, d, e and f, and the proportion of conductive carbon black(s) having a BET surface area of <1000 m²/g measured by the BET method to ASTM D 6556-04, as at Apr. 27, 2015, in an electrode layer after drying is in the range from 20% to 50% by weight, based on the sum total of b, c, d, e and f.

Auxiliaries

The mixture from step I may, as well as a, b, c, d and e, also comprise f auxiliaries and additives. Examples of these auxiliaries and additives are crosslinkers, thickeners, solvents, thixotropic agents, stabilizers, antioxidants, light stabilizers, emulsifiers, surfactants, adhesives, plasticizers, hydrophobizing agents, pigments, fillers, rheology improvers, degassing and defoaming aids, wetting additives and catalysts. The mixture from step I more preferably comprises wetting additives. Typically, the wetting additive is present in an amount of 0% to 2% in the mixture of a, b, c, d, e and optionally f. Typical wetting additives are, for example, Byk additives available from Altana, for instance: polyester-modified polydimethylsiloxane, polyether-modified polydimethylsiloxane or acrylate copolymers, and also, for example, C₆F₁₃-fluorotelomers.

Transducers

In particular, by the method described above, it is possible to produce an electromechanical transducer having a breakdown field strength of >40 V/μm in accordance with ASTM D 149-97a, as at Apr. 27, 2015, more preferably >60 V/μm, most preferably >80 V/μm, a volume resistivity of >1.5E10 ohm*m in accordance with ASTM D 257, as at Apr. 27, 2015, preferably >1E11 ohm*m, more preferably >5E12 ohm*m, most preferably >1E13 ohm*m, a dielectric constant of >5 at 0.01-1 Hz in accordance with ASTM D 150-98, as at Apr. 27, 2015, a layer thickness of a dielectric film, calculated as a monolayer, of <100 μm, and preferably >0.1 μm, more preferably >2 μm, and <100 000 layers.

Application of the Electrode Layer

The electrode layer may preferably be applied to the first part of the elastomer layer by spraying, pouring, knife-coating, brushing, printing, vapor-depositing, sputtering and/or plasma CVD. In particular, a suitable device for applying, such as a spraying device, a printing device, a rolling device, etc., may be provided. Printing processes that can be given by way of example here are inkjet printing, flexographic printing and screen printing. In a simple manner, it is possible to apply an electrode layer, in particular a structured electrode layer, to the elastomer film at least before a first folding step.

Preferably, the electrode layer is applied by means of a printing method.

In a further embodiment, the electrode layer may be mixed with a binder. This improves the mechanical cohesion of the layers of the multilayer electromechanical transducer. Furthermore, the electrode layer may preferably be dried before the folding step.

As already described, an electromechanical transducer has at least two superposed electrode layers, with a dielectric elastomer layer arranged in between; see, for example, FIG. 1. By applying a voltage, i.e. by applying different potentials, to the two opposing electrode layers, it is possible to bring about extension of the elastomer film in between. It will be apparent that, in the case of a sensor or generator application, extension of the elastomer film can bring about a certain voltage at the electrode layers and this can be tapped at the electrodes.

In the case of a multilayer electromechanical transducer, it is necessary that the stacked electrodes can be supplied with alternating potential. Preferably, a contacting electrode layer may be connected to first electrode layers of the electromechanical transducer, designed for applying a first electrical potential to the first electrode layers. A second contacting electrode layer may be connected to at least one second electrode layer, preferably a plurality of second electrode layers, of the electromechanical transducer, for applying a second electrical potential to the second electrode layers. In the electromechanical transducer, first electrode layers and second electrode layers may be arranged alternately. The same applies correspondingly to the tapping of voltages in the case of sensor or generator applications. In particular, the first electrode layers and the second electrode layers may be formed as essentially the same. For example, they may comprise a planar electrode area and a terminal lug for connecting the electrode area to a contacting electrode layer. Preferably, the terminal lugs of all of the first electrode layers in an electromechanical transducer may be aligned with a first same outer side of the transducer. Furthermore, the terminal lugs of all of the second electrode layers in an electromechanical transducer may be aligned with a second same outer side of the transducer, the first outer side being different from the second outer side. The two outer sides are preferably opposite outer sides.

In particular, in the case of an electromechanical transducer produced by the present process, the electrode layers have been applied to the elastomer films in such a way that they can be contacted from the sides and do not protrude beyond the edge of the dielectric film. The reason for this is that otherwise breakdowns can occur. Preferably, a safety margin may be left between the electrode and the dielectric, so that the electrode area is smaller than the dielectric area. The electrode may be structured in such a way that a conductor track is led out for electrical contacting. The electrode layers can be contacted in an easy way.

A further aspect of the invention is an electromechanical transducer having the above-described electrode.

A multilayer electromechanical transducer having at least one of the above-described electrodes, preferably at least two, can be produced by various methods known to those skilled in the art, for example by a folding method or by a layering method. Preferably, the individual layers are bonded to one another by means of a dielectric elastomer film and an adhesive; see, for example, FIG. 2. It is possible here to choose a laminate produced by a process of the invention or consisting of an electrode layer of the invention on a first dielectric elastomer film from starting point. Firstly, an adhesive, e.g. Dispercoll U XP 2643 or aqueous dispersions thereof, can be treated onto the surface of the first dielectric elastomer film remote from the surface having the electrode layer of the invention, and, in turn, a laminate, preferably produced by a process of the invention or consisting of an electrode layer of the invention on a first dielectric elastomer film, can be bonded to the electrode layer of the second laminate on this bonding surface. Alternatively or additionally, a further dielectric elastomer film can be bonded by means of an adhesive to the electrode layer of a laminate produced by a process of the invention or consisting of an electrode layer of the invention on a first dielectric elastomer film, in which case the surface of this second dielectric elastomer film remote from the bonding surface is in turn bonded to an electrode layer of a laminate, preferably produced by a process of the invention or consisting of an electrode layer of the invention on a first dielectric elastomer film, the adhesive advantageously having been applied on the second dielectric elastomer film. Alternatively, it is also possible, for example, to choose a laminate produced by steps I-III or consisting of an electrode layer of the invention, a first dielectric elastomer film and a second electrode layer, preferably one of the invention, as the starting point, and to bond further dielectric elastomer films to each of the two electrode layers, which are optionally bonded in turn, on their surfaces remote from the bonding surface, again by means of an adhesive, to further electrode layers of laminates, for example those of the invention, produced according to steps I-III or according to steps I and II (see, for example, FIG. 2).

Yet a further aspect of the invention is a component comprising an electromechanical transducer described above. The component may be an electronic and/or electrical device, in particular a module, automatic device, instrument or component part, comprising the electromechanical transducer.

A further aspect of the present invention is a use of an electromechanical transducer described above as an actuator, sensor and/or generator. The electromechanical transducer of the invention can be advantageously used in a multitude of very different applications in the electromechanical and electroacoustic sector, especially in the sectors of energy harvesting from mechanical vibrations, acoustics, ultrasound, medical diagnostics, acoustic microscopy, mechanical sensing, especially pressure, force and/or expansion sensing, robotics and/or communications technology. Typical examples thereof are pressure sensors, electroacoustic transducers, microphones, loudspeakers, vibration transducers, light deflectors, membranes, modulators for glass fiber optics, pyroelectric detectors, capacitors, control systems and “intelligent” floors, and also systems for conversion of mechanical energy, especially from rotating or oscillating motions, into electrical energy.

### EXAMPLES

The invention will now be more particularly elucidated by means of examples and FIGS. 1 and 2.

Unless indicated otherwise, all percentages are based on weight.

Unless stated otherwise, all analytical measurements were conducted at temperatures of 23° C. under standard conditions.

### Figures

FIG. 1 shows an electromechanical actuator comprising a laminate produced by a process of the invention, wherein the electromechanical actuator has a first electrode unit 10 and a second electrode unit 20 on the side of the dielectric elastomer film 30 remote from the first electrode unit 10. In addition, the actuator comprises a control unit 40 which forms contacts with the first and second electrode units 10, 20 and is set up to apply electrical voltage between the first and second electrode units 10, 20 and is additionally set up to allow an electrical current to flow through the first and/or second electrode unit 10, 20.

FIG. 2 shows a detail of a stack actuator comprising a laminate produced by a process of the invention, having a first electrode unit 10 and a second electrode unit 20 on the side of the dielectric elastomer film 30 remote from the first electrode unit 10, and dielectric elastomer films 50 which may be identical to the dielectric elastomer film 30, and which are each bonded to an electrode unit 10 or 20 by means of an adhesive 60.

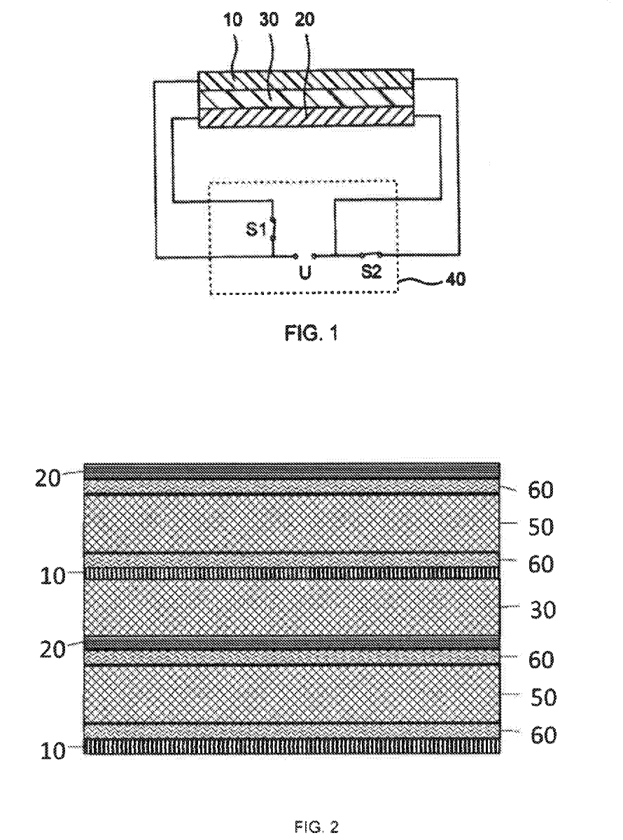

Methods:

Unless explicitly mentioned otherwise, NCO contents were determined by volumetric means to DIN-EN ISO 11909, as at May 7, 2015.

Hydroxyl numbers, OHN in mg KOH/g of substance, were determined in accordance with DIN 53240 as at December 1971.

The viscosities reported were determined by means of rotary viscometry to DIN 53019 at 23° C. with a rotary viscometer from Anton Paar Germany GmbH, Germany, Helmuth-Hirth-Str. 6, 73760 Ostfildern.

Measurements of film layer thicknesses of the dielectric were conducted with a mechanical gauge from Dr. Johannes Heidenhain GmbH. Germany, Dr.-Johannes-Heidenhain-Str. 5, 83301 Traunreut. The specimens were analyzed at three different locations, and the average value was used as representative measurement.

Measurements of the film layer thicknesses of the electrode layers were determined gravimetrically.

The tensile tests were carried out with a tensile tester from Zwick, model number 1455, equipped with a load cell with overall measurement range 1 kN in accordance with DIN 53 504 with a tensile velocity of 50 mm/min. The specimens used were S2 tensile specimens. Each measurement was carried out on three specimens prepared in the same way, and the average value of the data obtained was used for evaluation. The variables determined for this purpose were specifically tensile strength in [MPa], elongation at break in [%], and stress in [MPa] for 100% and 200% extension.

The determination of creep was likewise executed using the Zwicki tensile tester; the instrumentation corresponds to the experiment for determination of permanent extension. The specimen used here was a sample strip of dimensions 60×10 mm², clamped with clamp separation 50 mm. After very rapid deformation to 55 mm, this deformation was kept constant for a period of 30 min and the force profile was determined over this time. Creep after 30 min is the percentage stress reduction, based on the starting value directly after deformation to 55 mm.

The aim of the measurement is to examine the area resistance of an electrically conductive layer under a given mechanical stress.

For the determination of the resistance of a conductive layer, the cutting blade with the 150×15 mm² rectangular shape is to be used. The sample thus punched can be halved so as to give two test specimens. The samples are contacted by applying two strips of adhesive copper tape at a distance of 50 mm from one another on the test specimen. The sample is clamped between the two clamps in the material tester. The data are recorded by means of a multimeter. For this purpose, the sample should be contacted with the adhesive copper tape.

The resistance of conductive layers is determined by the following methods:

Conductivity under extension: In this test, the plot of force on the sample for a tensile stress at a traverse speed of 50 mm/min up to an extension of 100% is recorded; the resistance of the electrode is recorded at the same time.

Cyclical conductivity under extension: The 15×50 mm² sample is subjected to 1000 cycles between 5% and 15% extension, at 0.125 Hz; the resistance of the electrode is recorded.

Resistance under creep stress: Creep is measured according to the above method; the resistance of the electrode is recorded as well.

Substances and Abbreviations Used:
Desmodur® N100 biuret based on hexamethylene diisocyanate, NCO content 220±0.3% in accordance with DIN EN ISO 11 909, viscosity at 23° C. 10 000±2000 mPa·s, Bayer MaterialScience AG, Leverkusen, DE
P200H/DS polyester polyol based on 44.84% by weight of hexane-1,6-diol and 55.16% by weight of phthalic anhydride, molar mass 2000 g/mol, Bayer MaterialScience AG, Leverkusen, DE
Polyol PE5050 polyether polyol from Bayer MaterialScience AG, functionality 2, OH number 57 mg KOH/g and about 50% ethylene oxide content; remainder is propylene oxide.
   TIB KAT 216 dioctyltin dilaurate DOTL
   BYK 3441 polyacrylate-based surface additive, BYK-Chemie GmbH
   Methoxypropyl acetate and ethyl acetate from Sigma-Aldrich.
   Bayfol® EA 102 dielectric polyurethane elastomer film based on Desmodur N100 and P200H/DS in layer thickness 50 μm from Bayer MaterialScience AG
   Impranil DLU aliphatic polycarbonate ester polyetherpolyurethane dispersion, Bayer MaterialScience AG
   Impranil C solution aromatic polyester polyurethane, Bayer MaterialScience AG
   Impranil VPLS 2346 polyacrylate resin, melamine/formaldehyde-crosslinkable, Bayer MaterialScience AG
   Impranil DSB 1069 anionic aliphatic polyetherpolyurethane, Bayer MaterialScience AG
   Ketjenblack EC 600 JD conductive carbon black, AkzoNobel Functional Chemicals (see table 2)
   Hiblack 40B2 conductive carbon black, Orion Engineered Carbons LLC (see table 2)
   XPB 545 conductive carbon black, Orion Engineered Carbons LLC (see table 2)
   Printex XE-2B conductive carbon black, Orion Engineered Carbons LLC (see table 2)
   BYK 9077 solvent-free wetting and dispersing additive, BYK-Chemie GmbH
   Borchi Gen SN95 polyurethane-based dispersing additive, OMG Borchers GmbH
   Baytubes® D W 55 PV conductive dispersion containing 90 parts by weight of water, 5 parts by weight of carbon nanotubes and 5 parts by weight of polyvinylpyrrolidone, Bayer MaterialScience AG
   Baytubes® D W 55 CM conductive dispersion containing 90 parts by weight of water, 5 parts by weight of carbon nanotubes and 5 parts by weight of carboxymethyl cellulose, Bayer MaterialScience AG

For the coating experiments in the inventive examples, a Coatema coating system with 7 dryers in a continuous roll to roll process was used, or a laboratory bar-coating machine from Zenther for laboratory experiments or a screen-printing machine for the application of the electrode layers.

TABLE 1
Parameters of the individual layers from examples 1-4

| | | | SR | SR | |
|---|---|---|---|---|---|
| | Layer | | at 0% | at 15% | SR after |
| Example | thickness | Creep | extension | extension | 1000 cycles |
| No. | [μm] | [%] | [ohm/sq] | [ohm/sq] | Mean [ohm/sq] |
| 1a | 1.3 | 7.6 | 7325 | 12737 | 16000 |
| 1b | 4 | 13.1 | 4110 | 9200 | — |
| 2 | 4.5 | 38 | 1400 | 3830 | 2900 |
| 3 | 4.3 | 9.5 | 4117 | 9213 | 6710 |
| 4 | 0.8 | 9.5 | 27273 | 67100 | — |

TABLE 2
Classifications of conductive carbon blacks used

| | XPB | Hiblack | Printex | Ketjenblack |
|---|---|---|---|---|
| | 545 | 40B2 | XE-2B | EC 600 JD |
| BET m²/g | 375 | 120 | 1000 | 1400 |
| ASTM 6556 as at. | | | | |
| May 7, 2015 | | | | |
| Oil absorption | 175 | 150 | 420 | 510 |
| number - | | | | |
| OAN ml/100 g | | | | |
| ASTM D 24 14 as at | | | | |
| May 7, 2015 | | | | |
| Ash | <0.5% | — | <2% | <0.1% |
| DIN 53586A as at | | | | |
| May 7, 2015 | | | | |

### Example 1 (Inventive)

In a beaker, 88.2 parts by weight of 1-methoxy-2-propyl acetate MPA, 2.54 parts by weight of Impranil VPLS 2346 Bayer MaterialScience AG, 3.8 parts by weight of ethyl acetate, 1.06 parts by weight of BYK 9077, 0.44 part by weight of Ketjenblack EC 600 JD AkzoNobel Functional Chemicals specification d as per claim 1, 2.42 parts by weight of Hiblack 4032 Orion Engineered Carbons LLC specification e as per claim 1 and 1.54 parts by weight of XPB 545 Orion Engineered Carbons LLC specification e as per claim 1 are incorporated with an IKA Ultraturrax T25 rotor-stator system. Dispersion was effected at a speed of 20 000 to 25 000 revolutions per minute, for about 20 min. Subsequently, a structured surface of this dispersion was printed onto Bayfol EA 102 by means of screenprinting and dried around 120° C. for 4 minutes. The layer thickness was 1.3 μm in example 1a, and 4 μm in example 1b. The test results are in table 1.

In addition, the film was printed from the other side with electrode 1a and laminated on either side with a further layer of Bayfol EA 102 in order to test the adhesion of multiple layers. For this purpose, an AC voltage of 10 Hz and 1500 V was applied for 2 h. No delamination of the layers was observed.

### Example 2 (not Inventive)

In a beaker, 40 g of Baytubes® D W 55 PV Bayer MaterialScience AG were premixed with 4 g of Baytubes® D W 55 CM Bayer MaterialScience AG together with 33.3 g of water and 16 g of Impranil DLU Bayer MaterialScience AG in a SpeedMixer™ DAC 150.1 at 2000 rpm.

Subsequently, a surface of this dispersion was printed onto a PU film. The test results are in table 1, Creep is too high for use as an electromechanical transducer.

### Example 3 (Inventive)

2 parts by weight of Ketjenblack EC 600 JD specification d as per claim 1, 0.5 part by weight of BYK9077 dispersing aid and 83.4 parts by weight of 1-methoxy-2-propyl acetate were incorporated into 14.1 parts by weight of PE5050 polyol with an IKA Ultraturrax T25 rotor-stator system with an S 25 N-25 G-ST dispersing tool. Dispersion was effected at a speed of 20 000 to 25 000 revolutions per minute, for about 3 min. 6.75 g of Hiblack 40B2 specification e as per claim 1 are added to 41.9 g of this finished dispersion, and 0.015 g of TIB KAT 216 and 0.052 g of BYK3441 are added thereto. This mixture is premixed in a SpeedMixer™ DAC 150.1 at 2000 rpm. Finally, a maximum of 30 minutes before the actual printing method, 1.23 g of Desmodur N100 isocyanate are weighed in and the mixture is mixed again at 3500 rpm. Subsequently, a surface of this dispersion was printed onto a PU film. The test results are in table 1.

### Example 4 (Inventive)

In a beaker, 80.8 parts by weight of 1-methoxy-2-propyl acetate, 2.5 parts by weight of Impranil C solution Bayer MaterialScience AG, 11.2 parts by weight of ethyl acetate, 1.1 parts by weight of BYK 9077, 0.4 part by weight of Ketjenblack EC 600 JD, 2.4 parts by weight of Hiblack 40B2 Orion Engineered Carbons LLC specification e as per claim 1 and 1.5 parts by weight of XPB 545 Orion Engineered Carbons LLC are incorporated with an IKA Ultraturrax T25 rotor-stator system. Dispersion was effected at a speed of 20 000 to 25 000 revolutions per minute, for about 15 min. Subsequently, a surface of this dispersion was printed onto a PU film. The test results are in table 1.

### Example 5 (not Inventive)

The procedure was as in example 1, except without the BYK 9077 dispersing additive and with 3.6 parts by weight of Impranil VPLS 2346. The carbon particles agglomerated and it was not possible to produce a homogeneous layer. The viscosity was so high that the ink turns lumpy.

### Example 6 (not Inventive)

The procedure was as in example 1, except without the Impranil VPLS 2346 starting material for formation of a matrix polymer and with 90.74 parts by weight of MPA. It was possible to produce the dispersion, but the dry electrode barely stuck to the Bayfol EA 102. In the cyclic test under high voltage, the layers delaminated after only 5 min.

### Example 7 (not Inventive)

The procedure was as in example 1, except with 10 parts by weight of Impranil VPLS 2346 starting material for formation of a matrix polymer and with 80.74 parts by weight of MPA. The creep of the composite composed of electrode and Bayfol EA 102 was 50%, which is of no use for further application.

### Example 8 (not Inventive)

The procedure was as in example 1, but with a carbon black having a high BET surface area and without a carbon black having a low BET surface area: A film was produced according to example 1 of the application, with 88.2 parts by weight of MPA, 1.0 part by weight of Impranil VPLS 2346 Bayer MaterialScience AG, 0.42 part by weight of BYK 9077, and 1.7 parts by weight of Printex XE-2B Orion Engineered Carbons LLC, and applied to Bayfol EA 102. In the cyclic test under high voltage, the layers delaminated after only 8 min.

### Example 9 (not Inventive)

The procedure was as in example 8, but with XPB545 only rather than Printex XE-2B, a carbon black of low BET surface area. The carbon particles agglomerated and it was not possible to produce a homogeneous layer.

### Example 10 (Inventive)

In a beaker, 94.2 parts by weight of 1-methoxy-2-propyl acetate MPA, 1.1 parts by weight of BYK 9077, 0.5 part by weight of Ketjenblack EC 600 JD AkzoNobel Functional Chemicals, 2.6 parts by weight of Hiblack 40B2 Orion Engineered Carbons LLC and 1.6 parts by weight of XPB 545 Orion Engineered Carbons LLC are incorporated with an IKA Ultraturrax T25 rotor-stator system. Dispersion was effected at a speed of 20 000 to 25 000 revolutions per minute for 20 min. Subsequently, a structured surface of this dispersion was printed onto Bayfol EA 102 by means of screenprinting and dried at 120° C. for 4 min.

In addition, the film was likewise printed from the other side with the same electrode layer (electrode-film-electrode).

A tacky polyurethane-based dispersion of Dispercoll U XP 2643 from Bayer MaterialScience AG, diluted with water in a 1:10 ratio, was printed by means of a coating bar onto one surface each of two Bayfol EA 102 and dried at 100° C. for 7 min. The layer thickness was 2 μm. The creep of these tacky films was 4% in each case (film-adhesive).

The film which had been printed with electrode on both sides (electrode-film-electrode) was laminated on either side with a further layer of the adhesive-printed Bayfol EA 102, so as to form a film-adhesive-electrode-film-electrode-adhesive-film laminate, in order to test the adhesion of multiple layers.

For this purpose, an AC voltage of 10 Hz and 1500 V was applied for 2 h. No delamination of the layers was observed. Testing was conducted for a further 12 h, in which no delamination was observed.

### Example 11 (Inventive)

In a beaker, 88.2 parts by weight of 1-methoxy-2-propyl acetate MPA, 2.54 parts by weight of Impranil VPLS 2346 Bayer MaterialScience AG, 3.8 parts by weight of ethyl acetate, 1.06 parts by weight of BYK 9077, 0.44 part by weight of Ketjenblack EC 600 JD AkzoNobel Functional Chemicals, 2.42 parts by weight of Hiblack 40B2 Orion Engineered Carbons LLC and 1.54 parts by weight of XPB 545 Orion Engineered Carbons LLC are incorporated with an IKA Ultraturrax T25 rotor-stator system. Dispersion was effected at a speed of 20 000 to 25 000 revolutions per minute for 20 min. Subsequently, a structured surface of this dispersion was printed onto Bayfol EA 102 by means of screenprinting and dried at 120° C. for 4 min.

In addition, the film was likewise printed from the other side with the same electrode layer (electrode-film-electrode).

A tacky polyurethane-based dispersion of Dispercoll U XP 2643 from Bayer MaterialScience AG, diluted with water in a 1:10 ratio, was printed by means of a coating bar onto one surface each of two Bayfol EA 102 and dried at 100° C. for 7 min. The layer thickness was 2 μm. The creep of these tacky films was 4% in each case (film-adhesive).

The film which had been printed with electrode on both sides (electrode-film-electrode) was laminated on either side with a further layer of the adhesive-printed Bayfol EA 102, so as to form a film-adhesive-electrode-film-electrode-adhesive-film laminate, in order to test the adhesion of multiple layers.

For this purpose, an AC voltage of 10 Hz and 1500 V was applied for 2 h. No delamination of the layers was observed. Testing was conducted for a further 12 h, in which no delamination was observed.

A tacky polyurethane-based dispersion of Dispercoll U XP 2643 from Bayer MaterialScience AG, diluted with water in a ratio of 1:10, was printed by means of a coating bar onto Bayfol EA 102 and dried at 100° C. for 7 min. The layer thickness was 2 μm. The creep of this tacky film was 4%.

1.-14. (canceled)

15. A process for producing a laminate comprising an electrode layer and a dielectric layer, comprising the steps of:
I. applying a starting mixture for production of an electrode layer to a dielectric elastomer film, where the starting mixture consists of
a) an organic or aqueous solvent present in the starting mixture in the range from 50% by weight to 97% by weight based on the sum total of a, b, c, d, e and f; and
the sum total of b, c, d, e and fin the starting mixture is in the range from 50% by weight to 3% by weight based on the sum total of a, b, c, d, e and fin the starting mixture; where
b) is a dispersing aid, and
c) is a starting material for formation of a matrix polymer, preferably for formation of an elastomer, and
d) is at least one conductive carbon black having a BET surface area of ≥1000 m²/g measured by the BET method according to ASTM D 6556-04, as at Apr. 27, 2015, and
e) is at least one conductive carbon black having a BET surface area of <1000 m²/g, preferably <900 m²/g, more preferably <600 m²/g, measured by the BET method according to ASTM D 6556-04, as at Apr. 27, 2015, and
f) is at least one further auxiliary or additive, and
where
the proportion by weight of b in the sum total of b, c, d, e and f is in the range from 1 to 20 parts by weight,
the proportion by weight of c in the sum total of b, c, d, e and f is in the range from 10 to 70 parts by weight,
the proportion by weight of d in the sum total of b, c, d, e and f is in the range from 1 to 20 parts by weight,
the proportion by weight of e in the sum total of b, c, d, e and f is in the range from 1 to 60 parts by weight,
the proportion by weight of fin the sum total of b, c, d, e and f is in the range from 0 to 20 parts by weight,
when the sum total of b, c, d, e and f is set to 100;
II. drying the layer at 30 to 150° C.

16. The process as claimed in claim 15, wherein the starting material for formation of a matrix polymer leads to formation of a polyurethane.

17. The process as claimed in claim 15, wherein the ratio of d) to e) is in the range from 10:1 to 1:20, preferably in the range from 5:1 to 1:15, more preferably in the range from 1:2 to 1:10.

18. The process as claimed in claim 15, wherein the conductive carbon black having a BET surface area of <1000 m²/g consists of a mixture of conductive carbon black having a BET surface area of 300 m²/g to 1000 m²/g, preferably 300 m²/g to 900 m²/g, and one having a BET surface area of 50 m²/g to 300 m²/g.

19. The process as claimed in claim 15, wherein the dry electrode layer thickness is in the range from 0.1 μm to 5 μm, preferably from 0.2 μm to 3 μm, more preferably from 0.3 μm to 1 μm.

20. The process as claimed in claim 15, wherein the conductive carbon black having a BET surface area of <1000 m²/g has a BET surface area of <900 m²/g.

21. The process as claimed in claim 15, wherein the layer thickness of the dielectric elastomer film is in the range from 1 μm to 200 μm.

22. The process as claimed in claim 15, wherein the ratio of electrode layer thickness to dielectric elastomer film layer thickness is <0.06.

23. The process as claimed in claim 15, further comprising step III:
III. applying a starting mixture for production of a second electrode layer to the surface of the dielectric elastomer film remote from the first layer.

24. The process as claimed in claim 26, wherein the second electrode layer is produced in accordance with claim 15.

25. A further preferred embodiment relates to the process described herein, further comprising step IV:
IV. applying a further dielectric elastomer film by means of an adhesive to the electrode layer after step II or applying a further dielectric elastomer film by means of an adhesive to one of the two electrode layers after step III or applying one further dielectric elastomer film to each of the two electrode layers after step III.

26. A laminate consisting of a dielectric layer of elastomer film and an electrode layer, wherein the electrode layer consists of
b 1% to 20% by weight of dispersing aid,
c 10% to 70% by weight of matrix polymer, and
d 1% to 20% by weight of conductive carbon black having a BET surface area of ≥1000 m²/g measured by the BET method according to ASTM D 6556-04, as at Apr. 27, 2015, and
e 1% to 60% by weight of conductive carbon black having a BET surface area of <[see above] 1000 m²/g measured by the BET method to ASTM D 6556-04, and
f 0% to 20% by weight of at least one further auxiliary and/or additive,
where the sum total of b, c, d, e and f is 100% by weight.

27. An electromechanical actuator system comprising a first electrode unit (10) on a dielectric elastomer film (30) and a second electrode unit (20) on the side of the dielectric elastomer film (30) remote from the first electrode unit, produced by a process as claimed in claim 24, a control unit (40) which makes contact with the first and second electrode units (10, 20) and is set up to apply an electrical voltage between the first and second electrode units (10, 20), and is also set up to allow an electrical current to flow through the first and/or second electrode unit (10, 20).

28. A multilayer actuator comprising at least one unit consisting of a first electrode unit (10) on a dielectric elastomer film (30) and a second electrode unit (20) on the side of the dielectric elastomer film (30) remote from the first electrode unit, and at least one further dielectric elastomer film (50) which has been bonded by means of an adhesive (60) to one of the two electrode units (10, 20), wherein this unit has been produced by the process from claim 25.
